(19) United States
(12) Patent Application Publication
(10) Pub. No.: US 2003/0138573 A1
(43) Pub. Date: Jul. 24, 2003

(54) Method and Apparatus for Applying Material to Glass

(75) Inventors: Michael G. Mikhael, Tucson, Arizona (US); Angelo Yializis, Tucson, Arizona (US)

(73) Assignee: Glasshield Patent Holding Company, Ltd., Castlerock, 80104 (US)

(21) Appl. No.: 10/248,491

(22) Filed: Jan. 23, 2003

Related U.S. Application Data
(60) Provisional application No. 60/350,062, filed on Jan. 23, 2002.

(51) Int. Cl. H05H 1/24; C23C 16/00

(52) U.S. Cl. 427/569; 427/496; 118/718; 118/723 E

(57) ABSTRACT

### Abstract of Disclosure

A method of applying a polymer to a glass surface includes applying atmospheric plasma to a glass surface, applying a film of polymerizable fluid to the surface and curing the film with high-energy radiation. Apparatus for applying atmospheric plasma includes positive and ground electrodes, and an emitter strip of porous material with a plasma gas diffusing between the electrodes and through the emitter strip onto the glass surface.

### Cross Reference to Related Applications

This application claims the benefit of United States Provisional Application serial no. 60/350,062 filed January 23, 2002, pending.

### Background of Invention

Field of the Invention -- The invention generally relates to coating processes involving a preliminary or preparatory treatment by direct application of electrical, magnetic, wave, or particulate energy, especially to atmospheric plasma treatment of glass. The invention also relates to stock materials and to methods and apparatus for applying composites, including nonstructural laminates. Still another aspect of the invention relates to radiant energy and to irradiation of objects. The invention specifically relates to methods for applying material to glass and more particularly to a method and apparatus for reliably adhering a polymer material to a glass surface under atmospheric pressure conditions.

Background Art -- Plasma is an ionized form of gas and can be obtained using AC or DC power input and ionizing a gas medium. A plasma, commonly referred to as the fourth state of matter, is an ensemble of randomly moving charged particles with a sufficient particle density to remain, on average, electrically neutral. Plasmas are used in a very diverse range of processing applications ranging from manufacturing integrated circuits used in the microelectronics industry to treating polymer films and for the destruction of toxic waste. Plasma processes can be grouped into two classes, low and high density, and are often displayed in an electron temperature versus density phase-space plot. Low-density direct current and radio frequency glow discharges are usually nonequilibrium, i.e. the electron and heavy particle (ions, neutral) temperatures are not equal. Low-density plasmas have hot electrons (Tₑ>10⁴ K) with cold ions and neutrals. Energetic electrons collide with, dissociate, and ionize low-temperature neutrals, creating highly reactive free radicals and ions. These reactive species enable many chemical processes to occur with low-temperature feedstock and substrates. Low-density plasmas are usually associated with low material-throughput processes such as surface modification. In high-density, thermal plasmas such as atmospheric-pressure arcs and torches, electron temperature is equal to heavy particle temperature, and this provides an effective source of concentrated enthalpy, which can be used in areas such as melting and vaporization of materials.

Low density (or glow discharge) plasmas are used in a variety of processes such as surface treatment, physical sputtering, plasma etching, reactive ion etching, sputter deposition, plasma-enhanced chemical vapor deposition, ashing, ion plating, reactive sputter deposition, and a range of ion beam-based techniques, which all rely on the formation and properties of plasmas. The types of plasmas encountered in surface treatment processing techniques and systems are typically formed by partially ionizing a gas at a pressure well below atmosphere. For the most part, these plasmas are weakly ionized, with an ionization fraction of 10⁻⁵ to 10⁻¹. Electron cyclotron resonance (ECR) plasmas can have higher ionization at high powers. Low-density plasmas can be established by AC or DC power input, and these systems can have many different types of geometries, depending upon the application.

Plasma treatment of polymer films on a moving web removes the contaminants from the surface and functionalizes the polymer surface by introducing functional groups such as: hydroxyl (-OH), carbonyl (-C=0), carboxyl group (-COOH), or amino groups (NHₓ). This functionalization leads to better wettability and improved adhesion or bondability between polymer surfaces and other materials deposited on these surfaces. Numerous researchers have discussed various aspects of plasma treatment of polymer substrates. The main parameters for plasma treatment are as follows:

I. Input power

II. Plasma density

III. Pressure

IV. Gas composition and flow rate

V. System geometry

Prior known plasma treatment systems have been provided for functionalizing material surfaces, including polymer films, metal, fabric and paper. Functionalized film products and vacuum plasma technology offer a wide range of chemically modified polypropylene film surfaces for many uses. One type of known vacuum plasma treater combines a hollow cathode and magnets. The hollow cathode is positioned on one side of a moving web, while the magnets are placed on the other side of the moving web. By doing so, high intensity plasma is generated in the immediate vicinity of the web to be treated. In this configuration, during the negative part of the cycle, the hollow cathode creates intense plasma zones that are directed towards the film surface. During the positive cycle, the web becomes part of the sputtering cathode, and in addition to the treatment, it is actually sputtered by the bombardment of the reactive and/or with inert positive ions. This configuration provides a superior level of surface treatment.

United States Patent 6,118,218 to Yializis, et al. discloses a steady-state glow-discharge atmospheric plasma treatment (APT) system for functionalizing polymer films. The atmospheric plasma treatment system has unique advantages over the prior technologies of corona and flame treatment. The APT system allows uniform and homogenous high-density plasma at atmospheric pressure and at low temperatures, using a broad range of inert and reactive gases. This system can be used for treating and modifying the surface properties of organic and inorganic materials. The APT process treats and functionlizes films in a manner similar to a vacuum plasma treatment process. Testing has been successfully performed for the treatment or functionalization of various polymer films including polytetrafluoroethylene (PTFE), polypropylene (PP), polyethylene (PE), and polyethylene teraphthalate (PET) films on moving webs. The surface energies of the treated films increased substantially, without any backside treatment, thereby enhancing the wettability, printability and the adhesion properties of these films. Plasma treatment can clean and functionalize a surface to promote adhesion between various materials.

United States Patent 6,276,741 to Campfield, et al. discloses a method of applying a polymerizable fluid to peripheral portions of a glass windshield and thereafter curing the fluid to form an impact resistant barrier around the periphery of the windshield. However, creating reliable adhesion of materials to glass is difficult with known methods. Also, the prior known atmospheric plasma system of United States Patent 6,118,218, described above, functionalizes polymer films that are much thinner than the minimum usable thickness of glass.

Several patents show additional background. United States Patent 4,129,667 to Lorenz et al. discloses a radiation curable composition of polyurethane diacrylate.

United States Patent 5,028,453 to Jeffrey et al. discloses the treatment of glass and other surfaces in a vacuum vessel, using the plasma of a compound containing hydroxyl groups to cause the surface to become hydrophilic. Vacuum vessels are not practical for high speed treatment of large glass objects such as windshields.

United States Patent 5,376,400 to Goldberg et al. discloses a method carrying out graft polymerization in an aqueous solution under specific conditions that involve vacuum and other controls. The method is suited for treating medical instruments, devices, implants and contact lenses. However, the limitations in use of vacuum, polymerization in aqueous solution, and other limiting conditions would be difficult to adapt for a larger scale, commercial, non-medical purpose such as treating automobile windshields.

United States Patent 5,798,146 to Murokh et al. discloses two types of electrode and a method for charging a dielectric surface in the visible corona without degrading the surface. The electrodes are useable under atmospheric conditions. The first electrode is a ring, which charges the insulated surface of coated wire pulled through the center of the ring. The second electrode is a single needle operated without a ground wire. A dielectric tube surrounds the needle, and an air stream blows through the tube, around the needle, partially dispersing the corona at the tip of the needle. Objects placed in the remainder of the corona obtain a charged surface. Neither electrode offers a mechanism suitable for functionalizing the surface of a windshield.

United States Patent 6,270,902 to Tedeschi et al. discloses providing a functionalized tie layer to a surface by plasma treatment in a chamber that is first partially evacuated and then backfilled filled with special gas, or by a corona discharge. The method is disclosed for treating and forming small medical devices, such as catheters or guide wires. The methods are not practical for treating large glass objects such as windshields.

United States Patent 6,300,641 to Koh et al. discloses blowing reactive gas over a surface while irradiating the surface with energized ion particles in a vacuum condition.

It would be desirable to create suitable plasma heads and an application method that would allow the use of plasma technology for application of protective films to thick sheet substrates such as a glass windshield. Glass does not share the thin, flexible nature of films to which plasma technology typically has been applied.

It would be desirable to improve the wettability and adhesion of coatings on glass. Especially on an automotive glass windshield, preventing lift-off of an exterior coating is a continuing problem. Weather, physical contact with windshield wipers, general abrasion, and aerodynamic lifting all tend to degrade the adhesion between an external coating layer and a windshield. A method of creating a more reliable bond between a glass surface and a polymer is needed.

Useful protective coatings on an automobile windshield tend to be in the thickness range from 4-9 mils. A coating of this thickness range presents special difficulties. Often producing such a coating is time consuming and economically costly. Applying such a coating in liquid form and then curing it can result in poor uniformity. Optical properties also tend to be degraded, and adhesion may be difficult to achieve. Thus, a process and apparatus that can produce a coating in the range from 4-9 mils at high speed, with good uniformity, adhesion and optical properties is highly desirable.

To achieve the foregoing and other objects and in accordance with the purpose of the present invention, as embodied and broadly described herein, the method and apparatus of this invention may comprise the following.

### Summary of Invention

According to the invention, a polymer coating is applied to a surface of a glass substrate. In a method of application, first under atmospheric conditions plasma is applied to the glass surface in order to clean and functionalize the surface. Second, a film of polymerizable liquid is applied to the plasma treated surface. Finally, the film is cured by exposing it to high-energy radiation.

In more detail, the plasma is applied by supplying a plasma gas through a plasma head that carries a positive electrode and a negative electrode. The plasma gas is supplied from a location between these electrodes. The porous metal emitter supplies the plasma gas by diffusion, or a porous ceramic emitter supplies the gas in the same way.

The plasma head may have a structure especially suited for treating a glass substrate such as a windshield. The structure includes a central electrode and an annular or outer electrode. Each electrode has an opposite polarity chosen between positive or ground. A dielectric emitter laterally surrounds the central electrode and emits the plasma gas. An annular outer electrode laterally surrounds the dielectric emitter. The central and outer electrodes create a plasma discharge between them, and the dielectric emitter delivers plasma gas into the plasma created between the electrodes.

An alternate structure for treating the periphery of a windshield with a plasma head employs an elongated porous metal emitter for plasma gas. A first elongated tubular electrode is disposed in a parallel position to the emitter. The first electrode is offset to a first lateral side of the emitter and connected for positive electrical polarity. A second elongated tubular electrode is disposed in a parallel position to the emitter. It is offset to a second lateral side of the emitter, opposite from the first elongated electrode. The second electrode is connected for ground electrical polarity. The two electrodes create a plasma discharge between themselves, and the porous emitter delivers plasma gas into the plasma created between the electrodes.

When treating a windshield to form a protective coating at the periphery, the polymerizable liquid should be chosen to produce a thermoset amorphous film when cured. The polymerizable liquid preferably contains acrylate, methacrylate, epoxy, polyurethane, vinyl components, and mixtures of these ingredients; a photo initiator; and an ultraviolet stabilizer. This liquid may contain polyurethane diacrylate, tripropyleneglycol diacrylate, trimethylolpropane triacrylate, an adhesion promoter, and a photo initiator. This method allows application of an unusually thick film, sufficient to establish a cured film having a thickness of at least 0.004 inches.

The surface of the glass substrate may be the convoluted peripheral surface of an automobile windshield. In this case, atmospheric plasma is applied to a peripheral portion of the windshield by mechanically guiding relative movement on three axes between the windshield and a plasma head delivering plasma. The plasma head follows the convoluted peripheral surface of the windshield. Also, the plasma head maintains a substantially uniform spacing from the windshield at the convoluted peripheral surface.

One embodiment of a plasma head for treating a preselected width of a glass windshield is formed of a base carrying a first dielectric tube and a second dielectric tube. Each tube is of a predetermined length and the tubes are mutually parallel. The predetermined length is the preselected width of glass windshield for treatment. A positive electrode extends longitudinally within the first tube, and a ground electrode extends longitudinally within the second tube.

The first and second tubes carry an elongated emitter between themselves. The base at least partially defines a diffusion chamber in gas communication with the emitter. The chamber contains a plasma gas. A supply of plasma gas feeds the diffusion chamber. The emitter is an elongated strip of porous metal. It is parallel to the first and second tubes and diffuses plasma gas from the diffusion chamber and into the plasma.

A second embodiment of a plasma head for treating a windshield employs a central electrode, preferably of positive electrical polarity. A dielectric emitter laterally surrounds the central electrode and emits a plasma gas. An annular outer electrode laterally surrounds the dielectric emitter and is of opposite polarity from the central electrode. The central and outer electrodes create a plasma discharge between themselves. The dielectric emitter delivers plasma gas into the plasma discharge created between the electrodes.

In the second embodiment of a plasma head, the emitter is a porous dielectric layer that permits plasma gas to diffuse through it while insulating the central electrode from the outer electrode. Further, a dielectric layer may laterally surround the outer electrode.

The accompanying drawings, which are incorporated in and form a part of the specification, illustrate preferred embodiments of the present invention, and together with the description, serve to explain the principles of the invention. In the drawings:

### Brief Description of Drawings

Details of this invention are described in connection with the accompanying drawings that bear similar reference numerals in which:

Figure 1 is a perspective view of a plasma head that embodies features of the present invention.

Figure 2 is an end view of the plasma head of Figure 1.

Figure 3 is a perspective view of another plasma head embodying features of the present invention.

Figure 4 is a schematic view of the process embodied in the present invention.

### Detailed Description

A method embodying features of the present invention includes the steps of applying atmospheric plasma to the surface in order to clean and functionalize the surface, applying a film of polymerizable fluid to the surface; and curing the film with high-energy radiation. The plasma treatment cleans the glass surface by removing contaminates. The plasma treatment functionalizes by creating reactive species on the surface, such as free radicals, cations, or anions that will bind to the top coating and by creating oxygenated groups such as hydroxyl, carboxyl or carbonyl.

Steady-state glow-discharge atmospheric plasma is applied with a plasma head such as described hereinafter. The plasma head is positioned at a selected distance from the glass surface and directed to emit plasma towards the glass surface. The nominal selected distance is about 0.25 inch with a maximum preferred distance of about 0.5 inch. The plasma head is maintained at the selected distance from the glass surface, and the glass surface and plasma head are moved relative to each other to apply plasma to the portions of the glass surface that will receive the polymerizable film. The plasma head could be moved by hand over the glass surface. However, mechanical control of the plasma head is better suited to maintain a uniform distance between the plasma head and the glass surface. Preferably an industrial robot or like mechanism moves the plasma head over the glass surface, or the glass surface is moved mechanically relative to the plasma head.

Known methods may apply a polymerizable fluid to the glass surface. United States Patent 6,276,741, incorporated herein by reference, discloses suitable methods. The fluid is applied to a thickness of about 0.004 inch to 0.009 inch. The characteristics of suitable polymerizable liquids include:

A liquid with the right reactivity towards radiation polymerization.

A liquid with the right viscosity for the spraying equipment.

A liquid that is stable under transportation and storing conditions.

A liquid that produces thermoset (heat stable) amorphous (clear/transparent) film.

A liquid that produces well-adhered film to glass.

A liquid that produces an impact resistant/absorbent film.

A liquid that produces a photo-resistant (UV stable) film.

A liquid that produces moisture resistant film.

By way of example, and not as a limitation, a suitable polymer would be a blend of acrylate/methacrylate, epoxy, polyurethane, or vinyl components mixed with photo initiators and UV stabilizers. More particularly a suitable coating formulation could include polyurethane diacrylate (oligomer), tripropyleneglycol diacrylate (monomer), trimethylolpropane triacrylate (monomer), acrylated silicone (adhesion promoter) and a photo initiator such as 1-hydroxy cyclohexyl phenyl ketone, which is sold under the trademark Irgacure 184 by Ciba Chemicals .

The step of curing may be accomplished with any high-energy radiation such as ultra violet (UV) light, electron beam (EB), or gamma radiation.

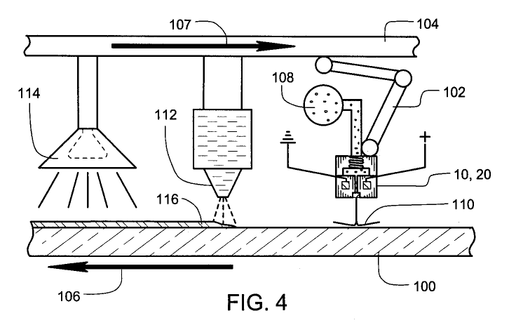

The method steps are illustrated in schematic Fig. 4. The invention is especially adapted for treating a work piece having the characteristics of a glass sheet or automobile windshield 100. This type of work piece has a substantial thickness and is rigid after forming. Prior known methods of applying plasma to a thin film or flexible web cannot be used. Instead, the work piece 100 may be moved, such as on a conveyor or by robotic means, signified by the arrow 106 below the work piece 100 in Fig. 4. Similarly, the treating equipment may be mounted on a robotic arm or other moveable mount 104 that is movable with respect to the work piece 100. Arrow 107 signifies that mount 104 may be relatively moveable with respect to the work piece 100. The plasma head may be one of the heads 10, 20 described below or another equivalently performing head.

In order to locate and maintain the head at a suitable or required spacing from the work piece, the head can be mounted on an automated, height adjustable arm mechanism 102. Such a mechanism can serve two functions. First, it moves the head over the surface of the work piece, which must include at least two axis movement in order to follow a convoluted surface. Second, the mechanism 102 can change the height position of the head dynamically as the head passes over a work piece 100 that is curved or irregular in surface profile, thus requiring a third axis of movement. The edge portions of a windshield are beneficially treated by this technology. Windshields come in many size and shape varieties. A plasma head must be guided in three axes to follow a convoluted edge path in order to treat such a variety of work pieces.

The plasma head 10, 20 of Fig. 4 is connected to a source of suitable plasma gas 108. The head also is connected to suitable voltage polarity and ground connections, indicated in the figures by conventional symbols. The plasma head can follow a three axis variable path to apply plasma 110 to preselected areas of a work piece 100, especially to the periphery. The source of plasma gas may be a pressurized tank of the gas.

A robotic carrier 104 also may guide an attached spray apparatus 112. After the gas fed plasma has functionalized the work piece, the spray apparatus 112 applies a film 116 of polymerizable fluid to the portions of the work piece previously treated by plasma 110. Similarly, the robotic carrier 104 may guide a source of curing radiation 114, especially high-energy radiation. This treatment ensures a good adherence of the film 116 to the work piece 100. The treatment provides a durable protective edge covering to a windshield.

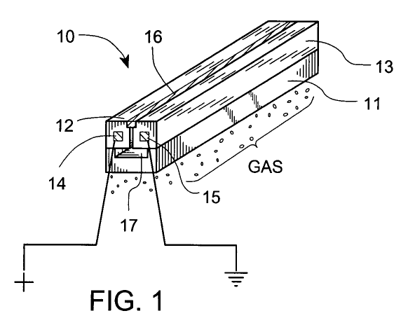

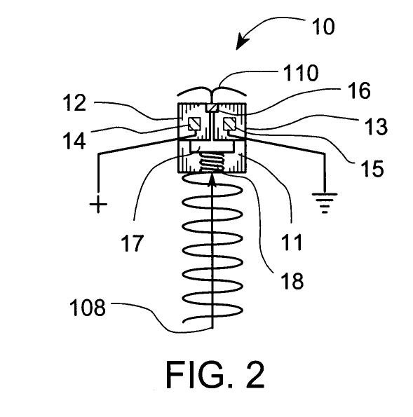

Figures 1 and 2 show a first plasma head 10 embodying features of the present invention. The head 10 includes an elongated base 11, which may be of a plastic material. The base carries an elongated, rectangular, dielectric first tube 12 and an elongated, rectangular, dielectric second tube 13. A positive electrode 14 is imbedded in and extends through the first tube 12. Similarly, a ground electrode 15 is imbedded in and extends through the second tube 13. The base 11 or tubes 12, 13 carry a parallel emitter strip 16. The tubes 12, 13, the electrodes 14, 15, and the emitter strip 16 are of approximately the same lengths and are arranged in parallel alignment. The length the parallel components may define a working width of the head 10. A suitable width is the width of the peripheral edge of a windshield that is to be treated by applying a protective coating.

A supply of plasma gas, preferably substantially at atmospheric pressure, is available, as schematically illustrated by the particles labeled "GAS" in Fig. 1. Such gas may be supplied from a pressure tank. A conventional pressure regulator can regulate gas pressure. Suitable plasma gases are disclosed in the incorporated U.S. Patent 6,118,218. A few examples are helium, argon, mixtures of an inert gas with nitrogen, oxygen, carbon dioxide, methane, acetylene, propane, ammonia, or mixtures thereof. Plasma gases often contain a substantial quantity of helium, such as forty-five percent or more.

The base 11 includes a longitudinal channel 17 extending along one side juxtaposed to the first and second tubes 12, 13. The channel 17 serves as a diffusion chamber. Fig. 2 shows a gas port 18 that is defined in and extends through the body of base 11 from the channel 17 to the opposite side. The gas port supplies plasma gas into the diffusion chamber from a source 108, Figs. 2 and 4. The first and second tubes 12 and 13 are mounted in a parallel, spaced, side-by-side relationship on the body 11, at least partially over the channel 17. The emitter strip 16 is mounted between the first and second tubes 12 and 13, opposite channel 17. The emitter strip 16 is comprised of a porous material, such as a porous metal layer that allows passage of a plasma gas.

The positive electrode 14 is connected to a radio frequency (RF) voltage with an output frequency ranging between 10 to 30 kHz. The ground electrode 15 is connected to ground. The output nominal RF voltage is between 350 and 9000 volts. The power that may be applied across the positive and ground electrodes 14, 15 may be from 100 to 5,000 watts. The gas port 18 is connected to a plasma gas source 108. A plasma gas is injected into the gas port 18 at substantially atmospheric pressure and allowed to diffuse along channel 17, between the positive and ground electrodes 14 and 15, through the emitter strip 16, and onto the glass work piece to be functionalized.

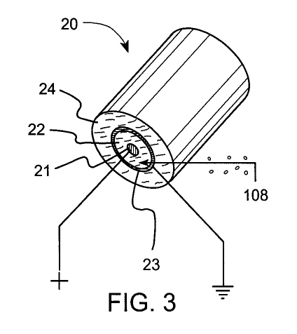

Referring to Figure 3, a second plasma head 20 also embodies features of the present invention. Head 20 includes positive and ground electrodes with an emitter located between them. For example, a first or central electrode, which may be chosen as positive or ground, is the elongated cylindrical electrode 21 near the center of the head. This electrode preferably is connected for positive polarity. A cylindrical porous ceramic portion 22 laterally surrounds the positive electrode 21. The porous ceramic portion serves as an emitter of plasma gas and also insulates the central electrode 21.

A second or cylindrical electrode 23 surrounds the porous ceramic emitter 22. The second electrode is of the opposite polarity from the first and preferably is connected for ground polarity. Thus, the emitter is located between the two electrodes and delivers plasma gas into the plasma discharge created between the two electrodes. A cylindrical ceramic insulator 24 surrounds the second or ground electrode 23.

Ceramic insulator 22 is sufficiently porous to allow passage of a plasma gas. Gas is injected through the porous ceramic portion 22, between the positive electrode 21 and the ground electrode 23. The plasma head 20 provides a uniform gas delivery.

The method and apparatus of the present invention are capable of providing an unusually thick coating of 0.004 inch to 0.009 inch. The coating is established at high curing speed and with good uniformity, adhesion and optical properties.

The foregoing is considered as illustrative only of the principles of the invention. Further, since numerous modifications and changes will readily occur to those skilled in the art, it is not desired to limit the invention to the exact construction and operation shown and described, and accordingly all suitable modifications and equivalents may be regarded as falling within the scope of the invention as defined by the claims that follow.

Claims

1. A method for applying a polymer coating to a surface of a glass substrate, comprising:
first, applying atmospheric plasma to the surface in order to clean and functionalize the surface;
second, applying a film of polymerizable liquid to the surface; and
third, curing the film by exposing it to high-energy radiation.

2. The method of Claim 1, wherein said first step further comprises:
supplying a plasma gas through a plasma head carrying a positive electrode and a negative electrode, wherein the plasma gas is supplied from a location between said electrodes.

3. The method of Claim 2, wherein said step of supplying a plasma gas further comprises:
supplying said plasma gas by diffusion through a porous metal emitter.

4. The method of Claim 2, wherein said step of supplying plasma gas further comprises:
supplying said plasma gas by diffusion through a porous ceramic emitter.

5. The method of Claim 2, wherein said step of supplying a plasma gas further comprises:
supplying said plasma gas through a plasma head including:
a central electrode having a polarity chosen between positive or ground;
a dielectric emitter laterally surrounding the central electrode and emitting the plasma gas; and
an annular outer electrode laterally surrounding the dielectric emitter and having a polarity chosen between positive or ground, opposite from the chosen polarity of said central electrode;
wherein the central and outer electrodes create a plasma discharge between them, and the dielectric emitter delivers plasma gas into the plasma created between the electrodes.

6. The method of Claim 2, wherein said step of supplying a plasma gas further comprises:
supplying said plasma gas through a plasma head including:
an elongated porous metal emitter, emitting the plasma gas;
a first elongated tubular electrode disposed in a parallel position to said emitter, offset to a first lateral side of the emitter, and connected for positive electrical polarity;
a second elongated tubular electrode disposed in a parallel position to said emitter, offset to a second lateral side of the emitter opposite from said first elongated electrode, and connected for ground electrical polarity;
wherein the first and second electrodes create a plasma discharge between themselves, and the porous emitter delivers plasma gas into the plasma created between the electrodes.

7. The method of Claim 1, wherein said second step further comprises:
applying a polymerizable liquid that produces a thermoset amorphous film when cured.

8. The method of Claim 1, wherein said second step further comprises:
applying a polymerizable liquid selected from the group consisting of acrylate, methacrylate, epoxy, polyurethane, vinyl components, and mixtures thereof;
a photo initiator; and
an ultraviolet stabilizer.

9. The method of Claim 1, wherein said second step further comprises:
applying a polymerizable liquid containing polyurethane diacrylate, tripropyleneglycol diacrylate, trimethylolpropane triacrylate, an adhesion promoter, and a photo initiator.

10. The method of Claim 1, wherein said second step further comprises:
applying a polymerizable liquid in quantity sufficient to establish a cured film having a thickness of at least 0.004 inches.

11. The method of Claim 1, wherein the surface of the glass substrate is the convoluted peripheral surface of an automobile windshield, and wherein said first step further comprises:
applying atmospheric plasma to a peripheral portion of said windshield by mechanically guiding relative movement on three axes between the windshield and a plasma head delivering plasma, such that:
said plasma head follows the convoluted peripheral surface of the windshield; and
the plasma head maintains a substantially uniform spacing from the windshield at the convoluted peripheral surface.

12. A plasma head for treating a preselected width of a glass windshield, comprising:
a base carrying a first dielectric tube and a second dielectric tube, each of a predetermined length and mutually parallel, wherein said predetermined length is the preselected width of glass windshield for treatment;
a positive electrode extending longitudinally within the first tube;
a ground electrode extending longitudinally within the second tube; and
an elongated emitter carried between the first and second tubes;
wherein said base at least partially defines a diffusion chamber in gas communication with said emitter and containing a plasma gas; and
a supply of plasma gas feeding the diffusion chamber.

13. The plasma head of Claim 12, wherein said emitter comprises an elongated strip of porous metal, parallel to said first and second tubes, diffusing plasma gas from said diffusion chamber.

14. The plasma head of Claim 13, wherein:
said positive and ground electrodes discharge a plasma between them; and
said porous emitter emits a plasma gas into the plasma.

15. A plasma head for treating a preselected width of a glass windshield with plasma, comprising:
a central electrode having a polarity chosen between positive or ground;
a dielectric emitter laterally surrounding the central electrode and emitting a plasma gas; and
an annular outer electrode laterally surrounding the dielectric emitter and having an opposite polarity from the central electrode;
wherein the central and outer electrodes create a plasma discharge between themselves, and the dielectric emitter delivers plasma gas into the plasma discharge created between the electrodes.

16. The plasma head of Claim 15, wherein said emitter comprises a porous dielectric layer, diffusing plasma gas while insulating said central electrode from said outer electrode.

17. The plasma head of Claim 15, further comprising a dielectric layer laterally surrounding said outer electrode.
